(19) United States
(12) Patent Application Publication
(10) Pub. No.: US 2006/0211249 A1
(43) Pub. Date: Sep. 21, 2006

(54) Pattern transfer method and exposure system

(75) Inventors: Akira Nakada, Kumamoto (JP); Kazumitsu Nakamura, Kumamoto (JP); Tatsuo Morimoto, Miyagi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: Japan Science and Technology Agency, Kawaguchi-shi (JP)

(21) Appl. No.: 10/537,487

(22) PCT Filed: Dec. 2, 2003
(86) PCT No.: PCT/JP03/15434

§ 371 Date: Apr. 4, 2006

(30) Foreign Application Priority Data
Dec. 3, 2002 (JP) 2002-351000

(51) Int. Cl. H01L 21/302; H01L 21/461

(52) U.S. Cl. 438/690

(57) ABSTRACT

Multilevel pattern registration is achieved by modifying the shape of an exposure pattern according to deviation of the shape of a microlithographically defined pattern due to distortion produced on a substrate. A substrate to be exposed is pretreated in a given manner. The substrate is photographed to obtain image data (1). Processing for extracting feature points is performed from the image data. Results of the extraction of feature points and design pattern data to be exposed are compared (2). Processing for detecting amounts of deviations is performed (3). Using results of the processing for detecting amounts of deviations, processing for modifying shapes of images in the design pattern data is performed (4). The images obtained by the results of the processing for modifying the shapes of the images are produced as an exposure pattern by an exposure image generator (5). The exposure pattern is exposed onto the exposed substrate (6).

### TECHNICAL FIELD

The present invention relates to a pattern transfer method and exposure machine. Especially, the invention relates to a pattern transfer method and exposure machine characterized in a method of modifying the shapes of exposure patterns to permit the exposure patterns to be overlapped according to distortion in the base pattern during a photolithographic process used when integrated circuits such as printed wiring circuit on a hard resin substrate, semiconductor circuit on a silicon wafer, or image display circuit on a glass substrate are fabricated.

### BACKGROUND ART

In recent years, various electronic devices have improved in performance. Concomitantly with this trend, the microlithography technology for semiconductor integrated circuits on silicon substrates is about to break through the region of 100-nm minimum feature size.

Meanwhile, reductions in minimum feature sizes of integrated circuits are essential for various techniques including techniques regarding printed wiring boards on resin substrate, techniques regarding System-in-Packages (SiPs), hybrid mounting techniques, techniques regarding liquid crystal displays and plasma displays on transparent glass substrate, and even techniques regarding electronic paper on softer resin substrate.

In the present situations, minimum feature sizes have reached several micrometers to tens of micrometers. However, it is considered that development of a further microlithography technique reaching the submicron range will be required within forthcoming ten years.

When various patterns such as interconnect patterns are formed on such a semiconductor IC device or printed wiring board, photolithography technology is used. For example, the patterns are formed by a reduction projection exposure method or proximity exposure method using a reticle or mask consisting of a chromium pattern formed on a quartz glass.

However, in recent years, to cope with high-volume, low-mix production, the ratio of the cost of fabricating the reticle or mask to the cost of developing the product has increased greatly. Therefore, the necessity of a reticle-free (or mask-free) pattern transfer method has increased.

Accordingly, a method of using a transmissive liquid crystal panel as a pattern generator without using photomasks has been proposed in recent years. An arbitrary pattern is formed on the transmissive liquid crystal panel and exposed onto a substrate to be processed (see, for example, JP-A-6-232024).

Furthermore, as the 21 century proceeds, various systems including exposure systems using liquid crystal display, optical exposure system using micro mirrors, and exposure systems relying on high-energy particle waves using electron beam or the like have been vigorously and rapidly researched, developed, and commercialized.

As a result of these efforts, it is almost certain that a completely reticle-free (or mask-free) pattern transfer technique will be put into practical use as a microlithography technique in integrated circuit manufacturing in near feature.

However, unlike single-crystal silicon substrates which have high mechanical hardness and whose amounts of distortion can be controlled down to relatively small amounts, hard resin substrates and transparent large-sized glass substrates are intrinsically have low hardnesses. In addition, the amount of distortion left in these substrates after microlithography is as much as tens of micrometers or more by the effects of thermal stress produced during process steps, variations in film stress caused by formation and etching of thin film, and mechanical stress produced from transporting and holding mechanisms.

Additionally, the amount of distortion has pattern dependence. It is unavoidable that the distortion is nonuniform across the whole substrate surface. Therefore, where such substrates are used, microlithography technology for achieving minimum feature sizes involves great difficulties.

That is, there is a demand for development of a pattern transfer method capable of reliably forming interconnects, contacts, and devices without producing electrical problems by coping with shifting of the microlithographically defined pattern shapes due to nonuniform distortion on the substrate.

Furthermore, with respect to single-crystal silicon substrate, as wafer diameter increase and pattern shrinkage progress, deviation of microlithographically defined pattern shapes due to in-plane distortion produced on the substrate presents problems.

Accordingly, it is an object of the present invention to provide a technique of achieving level-to-level registration by modifying the shape of an exposure pattern according to deviation of a microlithographically defined pattern shape due to distortion produced on the substrate.

### DISCLOSURE OF THE INVENTION

FIG. 1 is a diagram illustrating the principle of the present invention. Means for solving the problems in the invention are now described by referring to FIG. 1.

Referring to FIG. 1

(1) The invention is characterized in that in a pattern transfer method, \textcircled{1} a substrate to be exposed that has been pretreated in a given manner is photographed to obtain image data, \textcircled{2} processing for extracting feature points from the image data is performed, \textcircled{3} processing for detecting amounts of deviations is performed based on the comparison between the results of the extraction of the feature points and design pattern data to be exposed, \textcircled{4} processing for modifying the shape of image in the design pattern data is performed using the results of the processing for detecting the amounts of deviations, \textcircled{5} the image obtained by the results of the processing for modifying the shape is produced as an exposure pattern by an exposure image generator, and \textcircled{6} the exposure pattern is exposed onto the exposed substrate.

By extracting feature points from the image of substrate gained from the exposed substrate, i.e., from the image data, in this way, the amount of deviation from the data design pattern for each feature point can be detected. Therefore, the shape of the image in the design pattern data can be modified according to the amount of deviation. Consequently, a pattern transfer matched to the deviation of pattern on the exposed substrate caused by nonuniform distortion can be performed.

(2) The invention is also characterized in that, in (1) above, the design pattern data is any one of a printed wiring circuit pattern, a semiconductor circuit pattern, and a circuit pattern made of a combination thereof.

In this way, the design pattern data to which the present invention is applied can take any form. Typical examples of the design pattern data include a printed wiring circuit pattern, a semiconductor circuit pattern, and a circuit pattern made of a combination thereof. This can reduce the cost of a printed wiring board or semiconductor IC device.

(3) The invention is also characterized in that, in (1) above, in the pretreatment of the exposed substrate, there is the step of previously forming at least one layer of pattern in the design pattern data, and a film of a photosensitive material is subsequently applied to a top surface of the substrate to be exposed.

In this way, the given pretreatment of the exposed substrate includes the process step of previously forming a pattern of at least one layer in the design pattern data. After this pretreatment, the film of the photosensitive material is applied to the top surface of the exposed substrate. Consequently, a pattern exposure with good level-to-level pattern registration can be performed on the exposed substrate, if it is deformed.

(4) The invention is also characterized in that, in (3) above, in the pretreatment of the exposed substrate, at least four alignment patterns are formed in end portions of an effective area from which an image can be taken when light reflected from the substrate is photographed by the substrate image-taking imaging device, in addition to the design pattern.

In this way, in the given pretreatment of the exposed substrate, at least one dedicated alignment pattern is formed in end portions of the effective area and added to the IC pattern. When light reflected from the substrate is photographed by the substrate image-taking imaging device, an image can be taken from the effective area. This facilitates recognizing the whole range on the substrate surface to which a pattern is to be transferred. In consequence, the pattern transfer can be performed with better efficiency.

(5) The invention is also characterized in that, in (4) above, in the processing for extracting feature points, through-holes are used as the feature points, in addition to the alignment patterns.

In this way, in the processing for extracting feature points, through-holes are used as feature points in addition to the alignment patterns. This assures that contacts such as of a printed wiring circuit can be recognized. Consequently, an interconnect pattern that is prevented from electrically malfunctioning can be formed.

(6) The invention is also characterized in that, in (4) above, in the processing for extracting feature points, characteristic points at least around or inside a polygonal pattern or characteristic points on a straight or curved line are used as feature points, in addition to the alignment patterns.

In this way, in the processing for extracting feature points, points forming features around or inside a polygonal pattern (such as the vertices of the polygonal pattern typified by a rectangular pattern, the point of the center, or the center of gravity) or points forming features of a straight or curved line (such as both ends of the straight or curved line, points of bends, or a midpoint) are used as feature points. This can improve the pattern transfer accuracy in a semiconductor device fabrication process or a process of fabricating a liquid crystal display or plasma display, the process using many polygonal patterns such as rectangular patterns.

(7) The invention is also characterized in that, in (1) above, in the processing for detecting amounts of deviations, amounts of relative positional deviations are calculated for all feature points corresponding to both the image data and the design pattern data in a 1:1 relation.

In this way, in the processing for detecting the amounts of deviations, the amount of relative positional deviation of each of all feature points corresponding to both the image data and the design pattern data in a 1:1 relation is calculated, the image data being obtained from the substrate image-taking imaging device. In consequence, the direction and amount of distortion in each microscopic area can be known over the whole substrate surface. A pattern transfer can be performed while coping with distortion more flexibly.

(8) The present invention is also characterized in that, in (7) above, the processing for modifying shapes of images is carried out by dividing areas by a triangular mesh having identical meshes for both the image data and the design pattern data by the use of all the feature points corresponding in a 1:1 relation as vertices and bringing the shapes of the triangles in the triangular mesh in the design pattern data into agreement with the shapes of the respective triangles in the triangular mesh in the image data.

In this way, in the processing for modifying the shapes of the images, areas are divided by a triangular mesh having identical meshes, using all feature points corresponding in a 1:1 relation as vertices, for both the image data and the design data, the image data being obtained from the substrate image-taking imaging device. The shapes of the triangles in the triangular mesh in the design data are brought into agreement with the shapes of the respective triangles in the triangular mesh in image data obtained from the substrate image-taking imaging device. As a result, modification of the shapes in the design pattern data on a two-dimensional space is enabled, as well as movement of points.

(9) The invention is also characterized in that, in (8) above, in the processing for modifying the shapes of the images, an affine transform is used.

In this way, in the processing for modifying the shapes of images for bringing the shapes of the triangles into coincidence with each other, an affine transform including linear transform and translation is used. This permits translation, rotation, elongation, and shrinkage of areas on a two-dimensional space. The shapes of the image of the design pattern can be modified more smoothly.

(10) The invention is also characterized in that, in (1) above, in a case where the position of the exposed substrate is controlled using an accurate positioning stage having a repetitive positioning accuracy of more than ±11 nm (when length is taken as a unit), the position of the stage is controlled according to the result of the processing for detecting the amount of deviation. A stage control signal in a given format is produced. The accurate positioning stage is driven to move the processed substrate physically. In this way, control in which the amount of relative positional deviation of at least one feature point corresponding in a 1:1 relation is reduced to a minimum is performed prior to pattern transfer.

In this way, in the pattern transfer controller, the processing for controlling the stage position is performed according to the results of the processing for detecting the amount of deviation. A stage control signal in a given format is produced. The accurate positioning stage is driven to move the substrate physically. Control is performed to minimize the amount of relative positional deviation of at least one feature point corresponding in a 1:1 relation prior to pattern transfer. Thus, even when a stage having a relatively low positioning accuracy is used, a smooth pattern transfer can be performed.

(11) The present invention is also characterized in that, in (1) above, the material of the exposed substrate is a hard resin material containing a main component that is paper-based phenol, glass composite, glass epoxy, diarylphthalate, epoxy resin, oxybenzoyl polyester, polyethylene terephthalate, polyimide, polymethyl methacrylate, polyoxymethylane, polyphenylene ether, polysulfone, or polytetrafluoroethylene.

In this way, an integrated circuit can be built on various insulating structures closely related to our lives by using the various hard resin materials as recited above.

(12) The invention is also characterized in that, in (11) above, a single-crystal silicon region is present at least in a part of the exposed substrate made of any one of the hard resin materials described above.

By incorporating the single-crystal silicon region in at least a part of the substrate made of a hard resin material in this way, a hybrid IC structure (including various semiconductor devices built in a hard resin material) such as a System-in-Package (SiP) can be achieved.

(13) The invention is also characterized in that, in (1) above, the exposed substrate is made of any one of silicon wafer, transparent glass material, and ceramics.

By using a silicon wafer as the exposed substrate in this way, a pattern transfer can be performed in a corresponding manner to pattern thinning due to overetching during an etching step or pattern thickening due to a film formation step during a process of fabricating semiconductor devices.

When the substrate to be exposed is made of a transparent glass material or ceramic, a pattern transfer can be performed in a corresponding manner to pattern thinning due to overetching during an etching step or pattern thickening due to a film formation step during a process of fabricating liquid crystal displays, plasma displays, or SIPs.

(14) The invention is also characterized by an exposure machine having means for holding a substrate to be exposed that has been pretreated in a given manner and for producing an arbitrary exposure pattern according to input of an image signal, the machine comprising a pattern transfer system including optics for guiding light reflected from the exposed substrate into a substrate image-taking imaging device, the substrate image-taking imaging device for photographing light reflected from the substrate via the optics and gaining the photographed light as image data, an image signal creating device for creating an image signal, a pattern transfer controller for receiving the image data output from the substrate image-taking imaging device and outputting the image data to the image signal creating device, and a design pattern data storage device having a function of transferring design pattern data to the pattern transfer controller, and the pattern transfer controller has functions in which processing for extracting feature points from the image data obtained from the substrate image-taking imaging device is performed, processing for detecting amounts of deviations from the results of the extraction of the feature points and from the design pattern data is performed, processing for modifying the shape of the image in the design pattern data is performed using the results of the processing for detecting amounts of deviations, and the image obtained by the results of the processing for modifying the image is used as image data for the image signal creating device.

By using the exposure machine of the structure described above, a pattern transfer conforming to deviation of the pattern on the exposed substrate produced by nonuniform distortion can be performed.

(15) The invention is also characterized in that, in (14) above, the means for producing an arbitrary exposure pattern according to input of an image signal has a transmissive image display device.

By using the transmissive image display device in this way, an arbitrary exposure pattern can be produced within the exposure machine in a mask-free or reticle-free manner.

(16) The invention is also characterized in that, in (15) above, the substrate image-taking imaging device is placed in a position where light reflected from the substrate is photographed after passage through the transmissive image display device.

By transmitting the light reflected from the substrate through the transmissive image display device in this way, the pattern on the substrate and the image displayed on the transmissive image display device can be photographed such that the pattern and the displayed image overlap in physical position. This makes it unnecessary to prealign the physical position of the substrate and the physical position of the transmissive image display device. This can facilitate the work.

(17) The invention is also characterized in that, in (15) above, the transmissive image display device is a transmissive liquid crystal display.

The cost of the whole system can be reduced and the reliability can be improved easily by using a transmissive liquid crystal display which is fabricated generally widely in projector and other applications, is low in price, provides secured reliability in this way.

(18) The invention is also characterized in that, in (14) above, the exposure machine adopts a reduction projection exposure system.

By utilizing a reduction projection exposure system widely used in microlithography processes in the current region of several microns to submicrons in this way, ultrafine patterns can be easily transferred.

(19) The invention is also characterized in that, in (14) above, the exposure machine adopts a proximity exposure system.

By utilizing a proximity exposure system widely used in microlithography processes in the current region of hundreds of microns to several microns in this way, relatively thick patterns can be easily transferred.

(20) The invention is also characterized in that, in (14) above, the exposure machine adopts a magnified projection exposure system.

By adopting a magnified projection exposure system in this way, an interconnect pattern can be formed in a mask-free or reticle-free manner when a solar cell array is formed on the surface of a building member such as a roof.

(21) The invention is also characterized in that, in (14) above, there is provided an ultraaccurate positioning stage having a repetitive positioning accuracy of less than ±11 nm (when length is taken as a unit) for a mechanism for controlling the position of the exposed substrate.

Because there is provided the ultraaccurate positioning stage having a repetitive positioning accuracy of less than ±11 nm (when length is taken as a unit) for the mechanism for controlling the position of the substrate in this way, initial alignment of the exposed substrate is dispensed with. The pattern transfer sequence can be simplified.

Where higher positioning accuracy is required in future, the stage may be controlled extremely accurately with a stage control signal.

(22) The invention is also characterized in that, in (14) above, there is provided an accurate positioning stage having a repetitive positioning accuracy of more than ±11 nm (when length is taken as a unit) for a mechanism for controlling the position of the exposed substrate. The stage controls the position of the exposed substrate according to a stage control signal transmitted from the pattern transfer controller.

By providing the accurate positioning stage having a repetitive positioning accuracy of more than ±11 nm (when length is taken as a unit) for the mechanism for controlling the position of the substrate such that the substrate position is controlled according to a stage control signal transmitted from the pattern transfer controller in this way, a general stage can be used. The cost of the machine can be reduced. In addition, it is possible to cope with a wider range of configurations of exposure system.

(23) The invention is also characterized in that, in (21) or (22) above, the positioning stage has a non-resonant ultrasonic motor as its driving mechanism.

By driving the ultraaccurate positioning stage by the non-resonant ultrasonic motor in this way, a substrate can be transported accurately and at a high speed.

Furthermore, by driving the accurate positioning stage by the non-resonant ultrasonic motor, the stage can be made small and compact.

### BRIEF DESCRIPTION OF THE DRAWINGS

FIG. 1 is a diagram illustrating a conceptual configuration of the present invention.

FIG. 2 is a block diagram of a system for implementing a pattern transfer method in a first embodiment of the present invention.

FIG. 3 is a conceptual diagram of one example of exposure machine 10.

FIG. 4 is a conceptual diagram of another example of exposure machine 10.

FIG. 5 is a diagram illustrating a sequence of operations for performing a pattern transfer in the first embodiment of the invention.

FIG. 6 is a diagram illustrating a pretreatment step in the first embodiment of the invention.

FIG. 7 is a diagram showing one example of design pattern used in the first embodiment of the invention.

FIG. 8 is a diagram showing one example of method of dividing an area of a design pattern by pattern transfer controller 30.

FIG. 9 is a diagram illustrating a sequence of operations for creating a triangular mesh.

FIG. 10 is a diagram showing one example of method of detecting the amount of deviation of a real image pattern of lower-layer through-holes from a design position.

FIG. 11 is a diagram illustrating an example of division of an area of a real image pattern and modification of the shape of a design pattern area.

FIG. 12 is a diagram illustrating operations for rotating a design pattern area.

FIG. 13 is a diagram illustrating an operation for converting coordinate axes of a design pattern area.

FIG. 14 is a diagram illustrating an operation for expansive or contractive conversion from a design pattern area to a real image pattern area.

FIG. 15 is a diagram illustrating an operation for converting coordinates of a pattern area after expansion or contraction.

FIG. 16 is a diagram illustrating an operation for rotating a pattern area after expansion or contraction.

FIG. 17 is a diagram illustrating an example of creation of a transferred pattern of metal interconnects.

FIG. 18 is a diagram illustrating a real image pattern after transfer of an upper layer of metal interconnects.

FIG. 19 is a diagram of pretreatment steps included in a pattern transfer process in a second embodiment of the invention.

FIG. 20 is a diagram of a design pattern in the second embodiment of the invention.

FIG. 21 is a diagram illustrating an example of a method of dividing an area of a design pattern in the second embodiment of the invention.

FIG. 22 is a diagram illustrating an example of a method of detecting the amount of deviation of a lower-layer real image pattern from a design position.

FIG. 23 is a diagram illustrating an example of division of an area of a real image pattern and modification of the shape of a design pattern area.

FIG. 24 is a diagram illustrating an example of creation of a transferred gate pattern.

FIG. 25 is a diagram illustrating a real image pattern after transfer of an upper layer of gate electrodes.

FIG. 26 is a block diagram of a system for implementing a method of transferring a pattern in a third embodiment of the invention.

FIG. 27 is a conceptual diagram showing one example of exposure machine 80.

FIG. 28 is a conceptual diagram of another example of exposure machine 80.

FIG. 29 is a diagram illustrating a sequence of operations for transferring a pattern in the third embodiment of the invention.

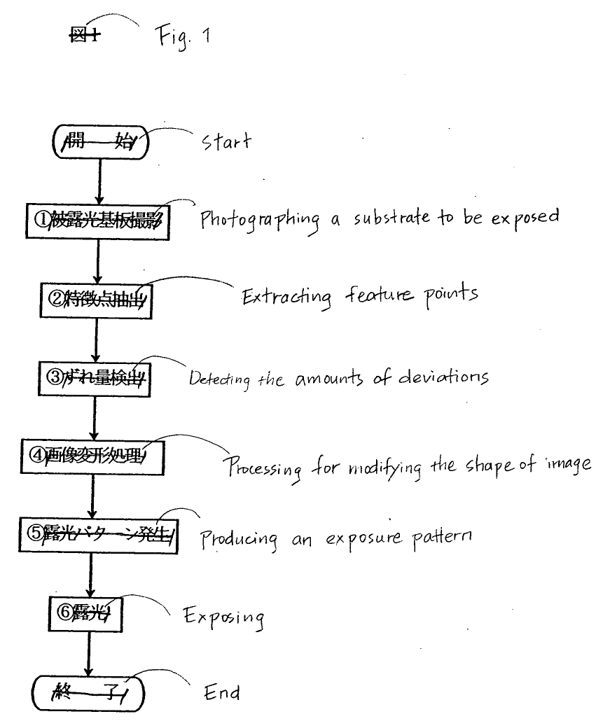

### BEST MODE FOR CARRYING OUT THE INVENTION

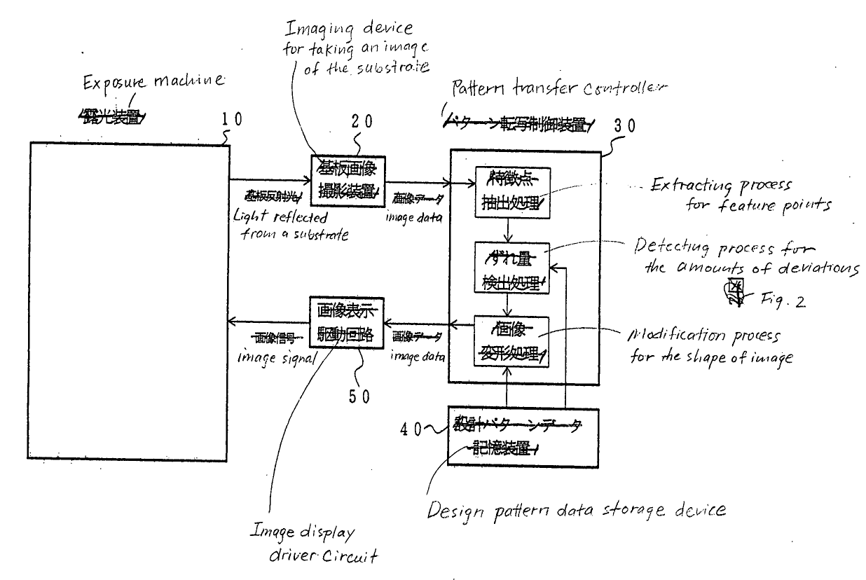

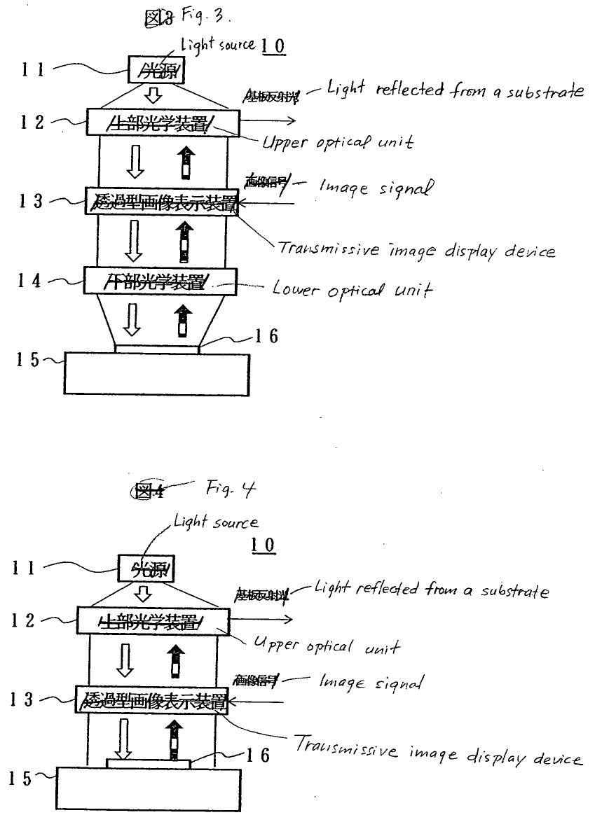

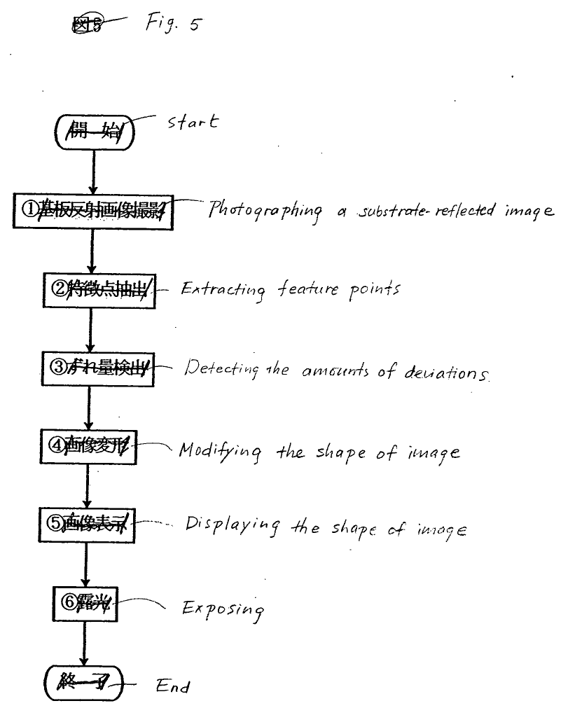

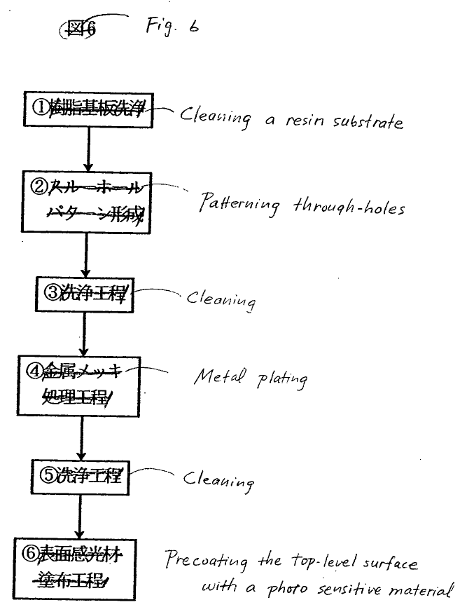

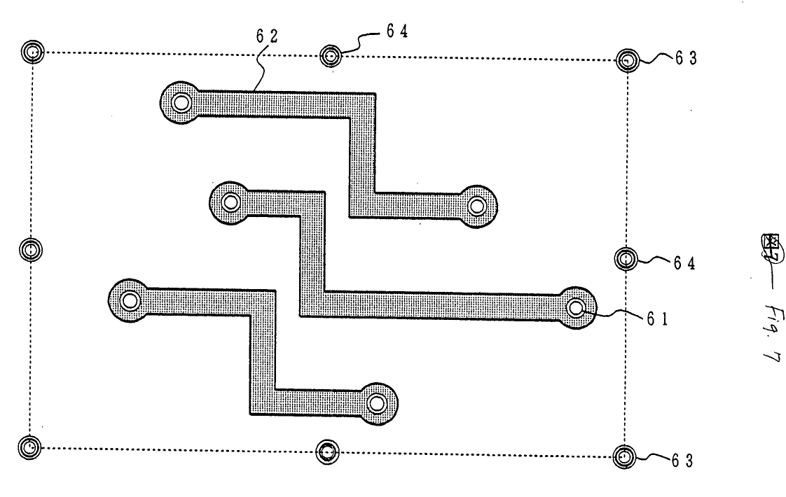

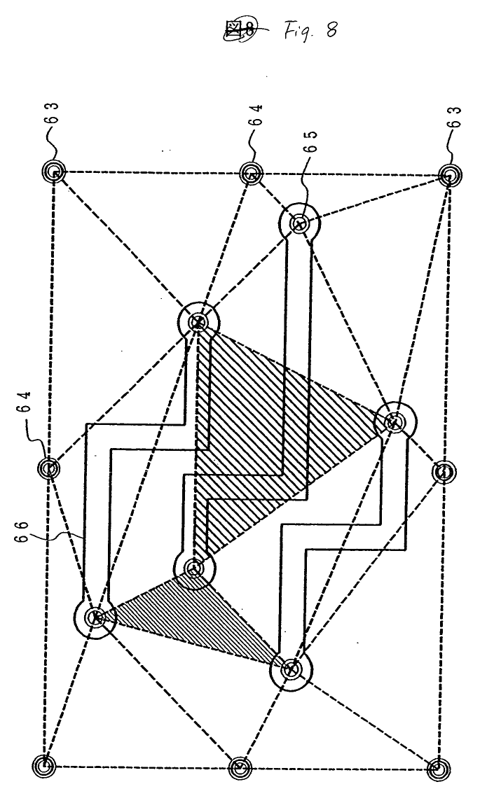

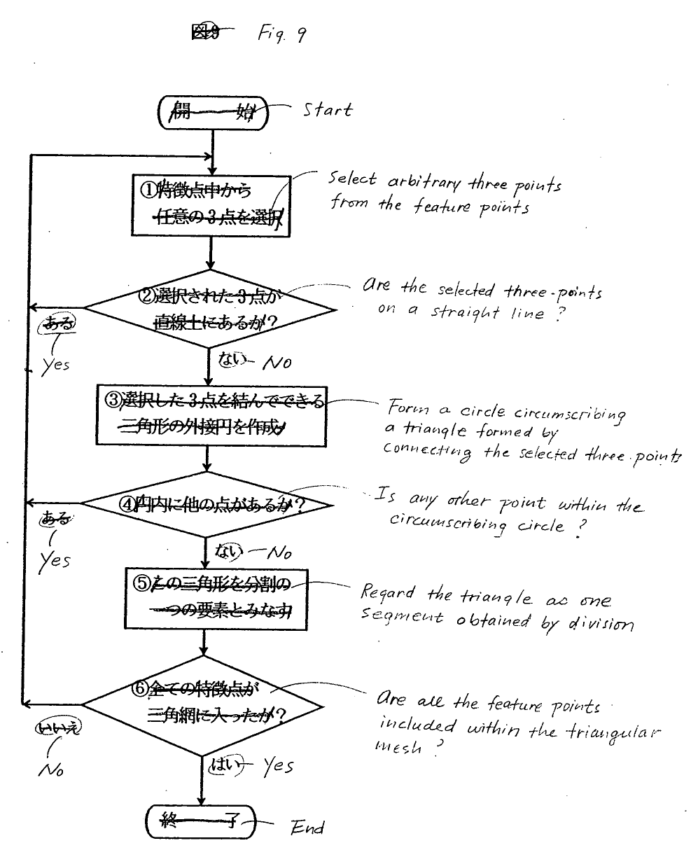

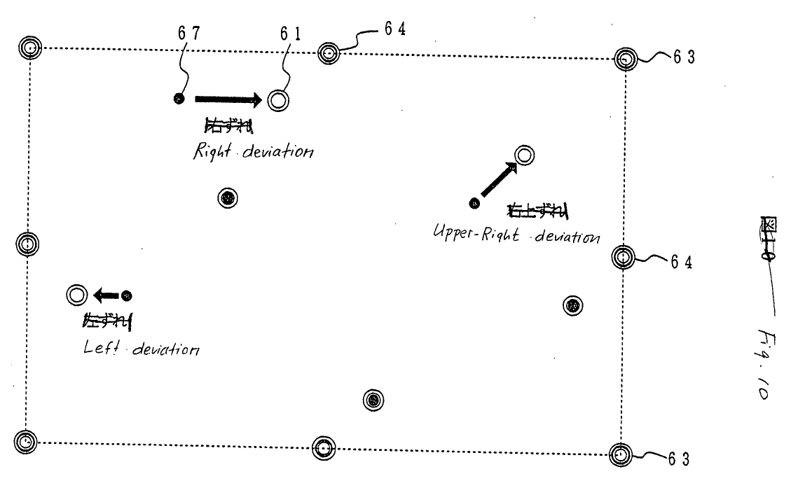

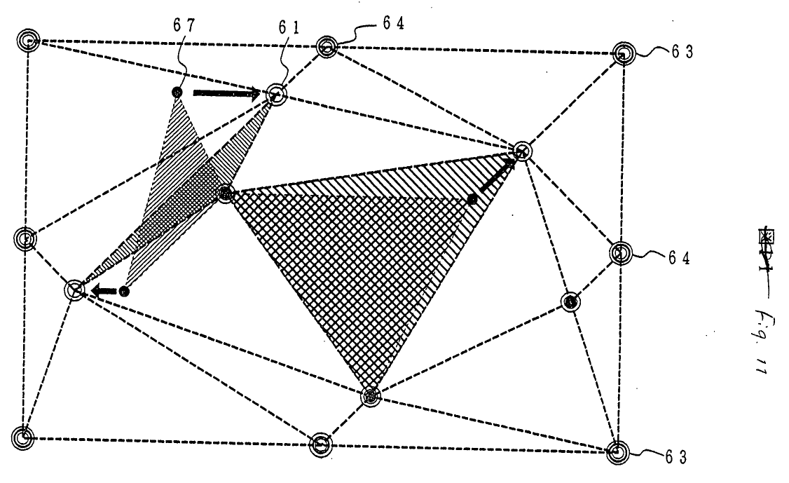

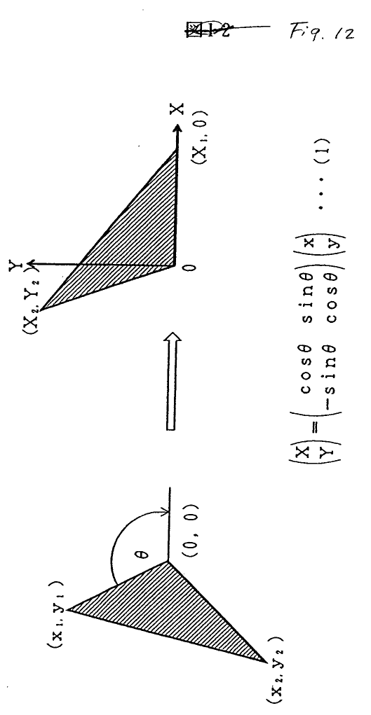

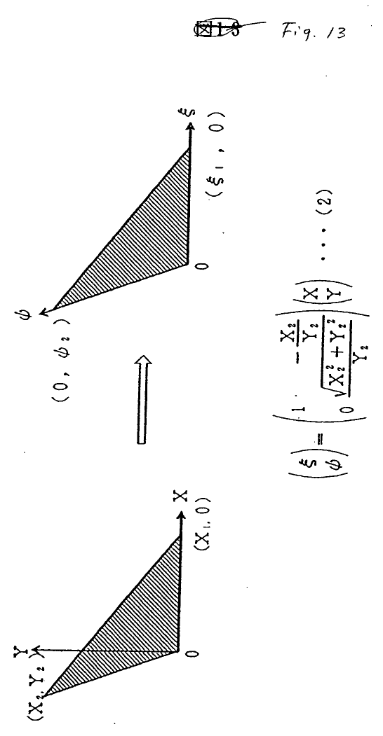

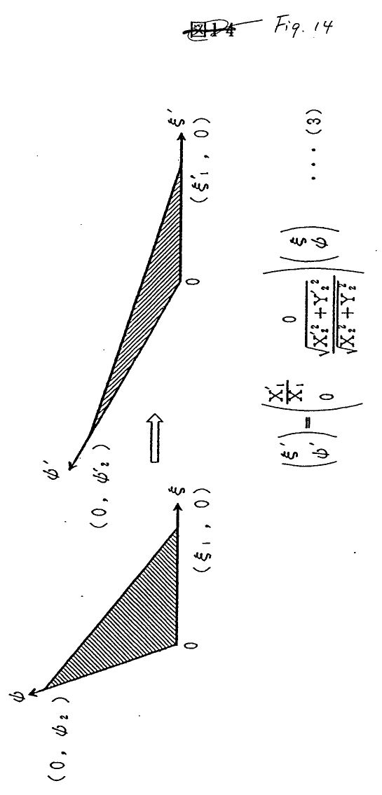

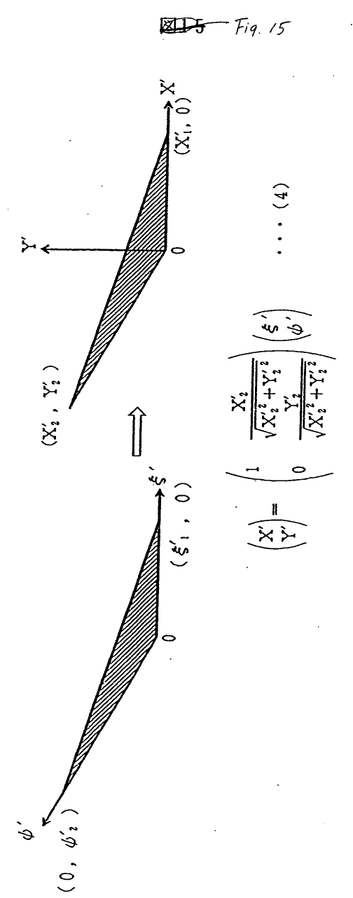

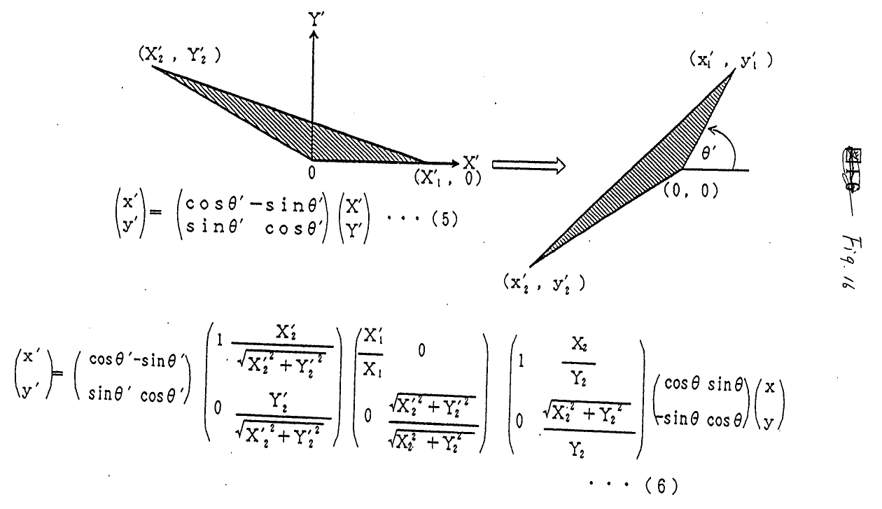

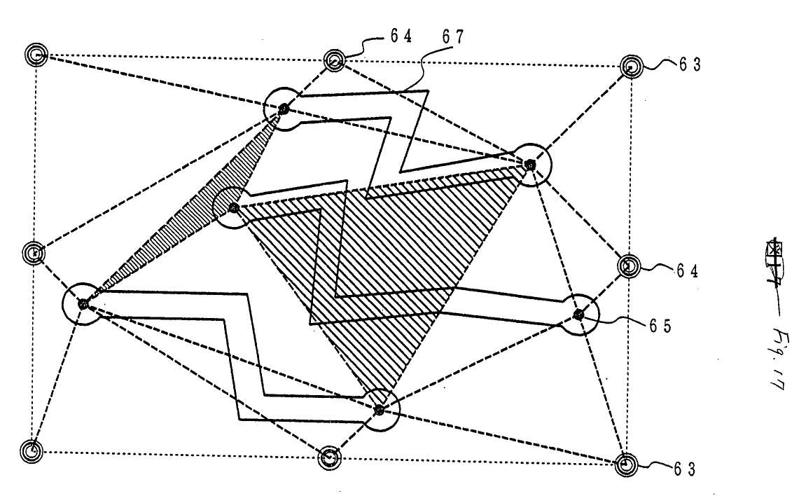

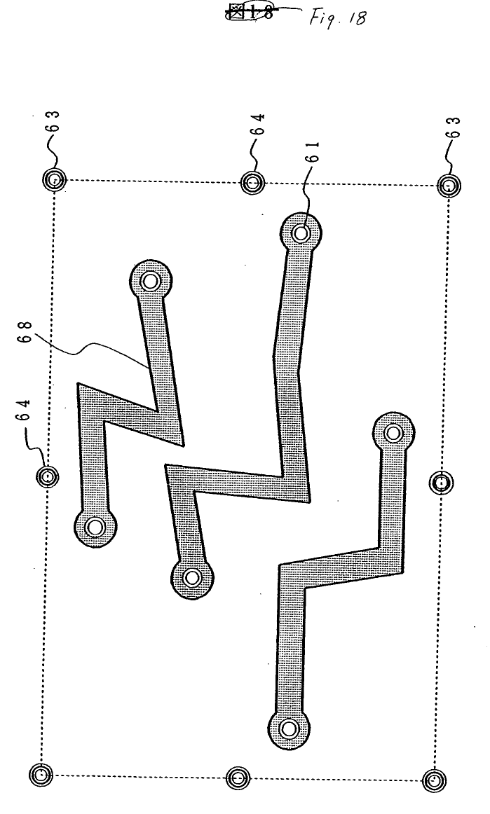

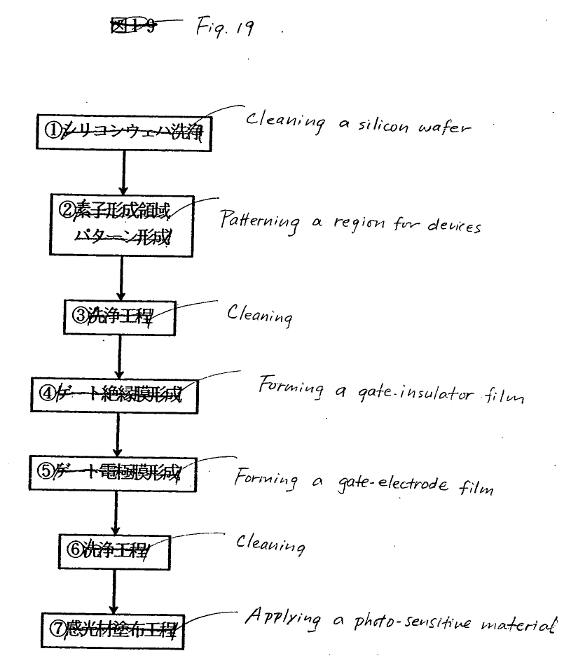

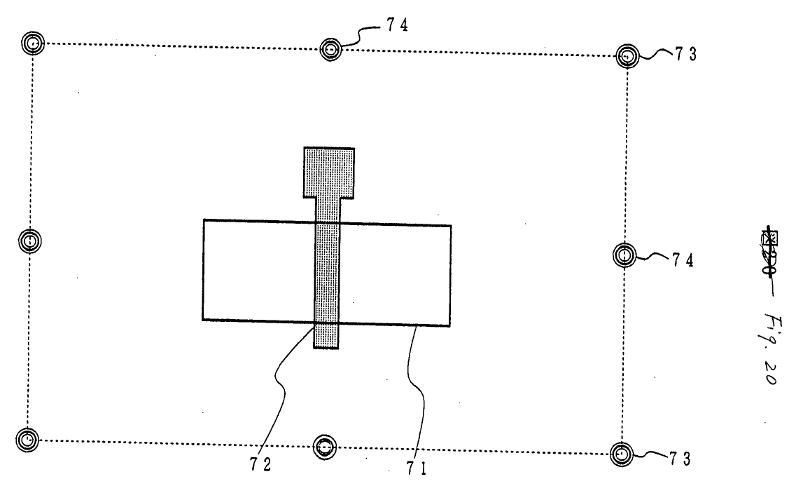

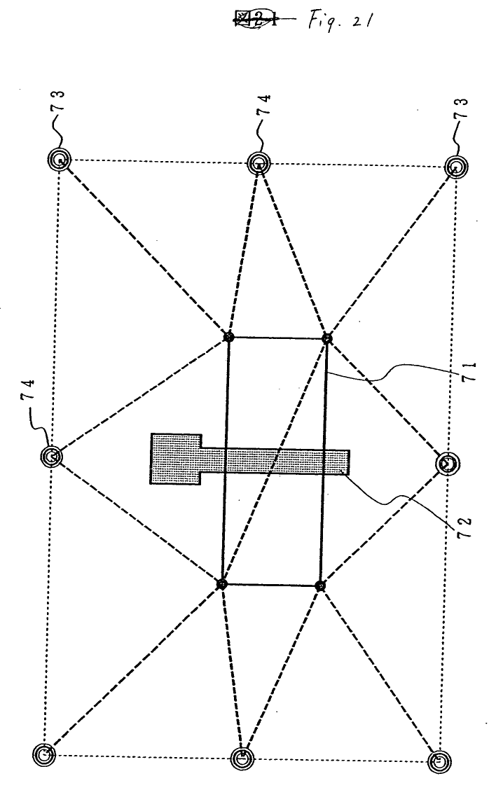

A pattern transfer method according to a first embodiment of the present invention is now described by referring to FIGS. 2-18.

Referring to FIG. 2

FIG. 2 is a block diagram of a system for implementing a pattern transfer method according to the first embodiment of the present invention. The system comprises an exposure machine 10 for loading a substrate to be exposed and for projecting a desired exposure pattern onto the substrate, an imaging device 20 for taking an image of the substrate, a pattern transfer controller 30, a design pattern data storage device 40, and an image display driver circuit 50. The imaging device 20 gains light reflected from the substrate as data about a real image. The controller 30 receives the data about the real image gained by the imaging device 20, the data being in an electronic data format. Data about a design pattern is stored in the storage device 40, which in turn outputs the data to the pattern transfer controller 30. The image display driver circuit 50 receives data about a modified image and outputs an image signal to an exposure pattern generator equipped in the exposure machine 10.

The pattern transfer controller 30 which receives electronic data format of the real image data gained by the substrate image-taking imaging device 20 has a function of extracting feature points corresponding to a pattern formed on the substrate (such as a center point of an alignment pattern, center point of a through-hole pattern, and vertices of a rectangle on the real image pattern) (i.e., real image data) by comparing the feature points against a predetermined pattern shape to know whether the points match the predetermined pattern shape.

The pattern transfer controller 30 has a function of detecting the amounts of deviations of a real image pattern on the exposed substrate from the coordinates of feature points by correlating the coordinates of the feature points extracted as described above with the respective coordinates of the feature points indicated by data about the design pattern called from the design pattern data storage device 40.

Furthermore, the pattern transfer controller 30 has a function of modifying the shape of the image by bringing the feature points indicated by the design pattern data into coincidence with the feature points of the real image pattern on the substrate according to the amounts of deviations.

In this case, a high-resolution area sensor including a semiconductor light-receiving device such as CCDs is preferably used as the imaging device 20 for taking an image of the substrate.

The required resolution is determined by the minimum feature size. In this embodiment, the effective pattern area that can be transferred in one sequence is set to 10 mm square, for example. The minimum feature size is set to 10 μm.

At this time, if it is assumed that a bare minimum number of pixels on the real image is 1 pixel/10 μm, and if a high-resolution area sensor having about 5 million pixels (3008 pixels×1960 pixels) is used, the size of the substrate image corresponding to the effective area of the area sensor is 30.08 mm×19.60 mm. Hence, the effective pattern area 10 mm square can be accepted sufficiently.

Preferably, the data format of the real image data created by the imaging device 20 for taking a substrate image is a bitmap data format representing each pixel. A data format of data compressed by JPEG, TIFF, PNG, VQ, or Run Length Encoding may also be used.

Where a data format compressed to improve the system communication rate is used, an image compressed in a non-reversibly deteriorates in quality. Therefore, it is obvious that the resolution may be improved equivalently by a different operation using an algorithm for extracting feature points as described later.

Referring to FIG. 3

FIG. 3 is a conceptual diagram of one example of the exposure machine 10. The shown exposure machine corresponds to a reduction projection exposure system typified by a stepper.

The exposure machine 10 includes a light source 11, an upper optical unit 12 for collimating light from the light source 11, a transmissive image display device 13 for producing an exposure pattern corresponding to design pattern data according to an image signal, a lower optical unit 14 for demagnifying the collimated beam transmitted through the display device 13, and an ultraaccurate positioning stage 15 for holding the exposed substrate 16.

Preferably, a transmissive liquid crystal display which is fabricated generally widely in projector and other applications, is low in price, provides secured reliability is used as the transmissive image display device 13. As a result, the cost of the whole system can be reduced and the reliability can be improved easily.

A positioning stage which has a repetitive positioning accuracy of less than ±11 nm (when length is taken as a unit) and which is driven by a non-resonant ultrasonic motor is used as the ultraaccurate positioning stage 15.

When light reflected from the substrate is gained, the wavelengths of light transmitted through the upper optical unit 12 are filtered out to prevent the photosensitive material applied to the surface of the substrate from being sensitized to the light from the light source 11.

For example, where a pattern is transferred to the photosensitive material using the g-line having a wavelength of 436 nm from a high-pressure mercury lamp, the e-line having a longer wavelength of 546 nm is used.

In addition, a separate light source such as a halogen lamp may be used. The wavelength of light from this halogen lamp which is the same as the wavelength of light used for exposure is cut off.

The light reflected from the exposed substrate 16 arrives at the upper optical unit 12 through the lower optical unit 14 and the transmissive image display device 13. Then, the upper optical unit 12 outputs the light reflected from the substrate to the substrate image-taking imaging device 50 mounted outside via optics such as a half mirror or window.

Referring to FIG. 4

FIG. 4 is a conceptual diagram of another example of the exposure machine 10. The shown exposure machine corresponds to the proximity exposure system typified by a mask aligner.

Since this exposure machine 10 is similar in configuration with the exposure machine shown in FIG. 3, its detail description is omitted. However, the difference is that the lower optical unit is not mounted. The collimated light transmitted through the transmissive image display device 13 directly illuminates the surface of the exposed substrate 16 in a 1:1 relation.

Referring to FIG. 5

FIG. 5 is a diagram illustrating a sequence of operations for performing a pattern transfer in accordance with the first embodiment of the invention. The reduction projection exposure system shown in FIG. 3 is described below.

\textcircled{1} All pixels are placed in a transmissive mode. A wavelength of light to which the photosensitive material applied to the exposed substrate 16 is not sensitive is directed from the light source 11 at the transmissive image creation device 13 built in the exposure machine 10. The light reflected from the substrate 16 is photographed by the substrate image-taking imaging device 50 via the image creation device 13 and the upper optical unit 12.

In this case, the photosensitive material is relatively transparent to visible light and so the pattern formed on the exposed substrate can be read via the photosensitive material.

Then, \textcircled{2} the pattern transfer controller 30 extracts feature points from the image formed by the light reflected from the substrate. Then, \textcircled{3} the amounts of deviations are detected from the extracted feature points. Then, \textcircled{4} based on the detected amounts of deviations, the shape of the image indicated by the design pattern data read in from the design pattern data storage device 40 is modified.

\textcircled{5} After the modification, the image data is input as an image signal into the transmissive image creation device 13 forming the exposure machine 10 to produce an exposure pattern on the image creation device 13.

\textcircled{6} Then, the wavelength of light to which the photosensitive material is sensitized is directed at the transmissive image creation device 13 producing the exposure pattern. The transmitted light is focused, demagnified, and projected onto the surface of the exposed substrate 16 by the lower optical unit 14, this performing exposure.

Prior to the exposure step, a holding jig such as pins or a frame is mounted on the ultraaccurate positioning stage 15. The side surface of the exposed substrate 16 whose outer contour is already known is made to bear against the holding jig, thus performing positioning.

The positioning accuracy relying on the holding jig at this time is determined by the amount of margin of the coating over the whole area of transferred pattern on the substrate 16 relative to the whole effective exposed area whose pattern can be transferred by the transmissive image display device 13.

When each pixel size of the transmissive image display device 13 is 20 μm square, for example, when a 5:1 reduction projection is performed, the positioning accuracy per pixel is 4 μm.

In this case, when the positioning accuracy of the exposed substrate 16 on the ultraaccurate positioning stage 15 determined by the holding jig is ±50 μm, when the amount of margin of the coating is 100 μm, then satisfactory results arise. That is, the effective exposure area is previously determined, taking account of the amount of margin of the coating about 25 pixels (=100 μm/4 μm).

Before the image formed by the light reflected from the substrate is taken, the exposed substrate is pretreated. The pretreatment of the exposed substrate is now described by referring to FIG. 6.

Referring to FIG. 6

FIG. 6 is a diagram illustrating pretreatment steps according to the first embodiment of the invention. \textcircled{1} First, a resin substrate which forms the processed substrate and to which a pattern should be transferred is cleaned. \textcircled{2} Then, a pattern of through-holes is created. \textcircled{3} Then, the resin substrate having the pattern of through-holes is cleaned. \textcircled{4} Thereafter, the inside wall of each through-hole is plated with a metal. \textcircled{5} Then, the plated resin substrate is cleaned. \textcircled{6} Finally, the top-level surface of the resin substrate is precoated with a photosensitive material.

Referring to FIG. 7

FIG. 7 is a diagram showing one example of design pattern used in the first embodiment of the invention. In this case, a pattern formed on a printed wiring circuit present on a resin substrate is transferred.

This design pattern is an example of design pattern when the through-holes 61 formed in the aforementioned pretreatment step are located in a lower layer and metal interconnects 62 are formed in an upper layer. Separate alignment patterns 63 and 64 covering 8 locations in total at the ends of the effective exposure area in the lower layer are formed.

The alignment patterns 63 and 64 are formed independently as circuit patterns. For example, they are through-holes.

In this case, the effective exposure area is preferably generally rectangular in shape. Accordingly, when the alignment patterns cover the four vertices of the effective exposure area, then satisfactory results will be obtained.

The other four alignment patterns 64 formed in the four sides, respectively, are added to permit a pattern transfer to be performed more exactly according to actual distortions in the patterns.

Referring to FIG. 8

FIG. 8 shows a manner in which an area of a design pattern is divided by the pattern transfer controller 30. The center points of the alignment patterns 63, 64, and the center points of through-hole patterns 65 are used here as feature points. Indicated by numeral 66 are interconnect patterns.

The design pattern read in from the design pattern data storage device 40 is used to divide the whole effective exposure area using the feature points described above and a triangular mesh. For the sake of convenience of illustration, some triangles are hatched to emphasize them. It is to be noted that not only these hatched portions are subsequently processed but all the triangles are obviously processed similarly.

The area is so divided by the triangular mesh pattern that all the triangles are made as close as possible to regular triangular form and that inclusion of non-regular triangular forms is minimized. This makes it easy to make uniform the accuracy of conversions performed later.

In this case, in the process step of dividing the area into triangles close to regular triangular form, a method of triangulation based on the principle of a maximum-minimum angle criterion, known as creation of a Delaunay triangular mesh in the field of computational geometry, is implemented. A specific diagram for dividing the area is described below by referring to FIG. 9.

Referring to FIG. 9

FIG. 9 is a diagram illustrating a sequence of operations for creating a triangular mesh. \textcircled{1} First, arbitrary three points are selected from the aforementioned feature points. \textcircled{2} A decision is made as to whether the selected three points are on a straight line. If the result of the decision is affirmative (i.e., the result is YES), control returns to step \textcircled{1} above. \textcircled{3} If the result of the decision is negative, a circle circumscribing a triangle formed by connecting the selected three points is formed. \textcircled{4} Then, a decision is made as to whether there is any other feature point within the circumscribing circle. Note that points on the circumference of the circumscribing circle are regarded as being outside the circle. If the result of the decision is affirmative (the result of the decision is YES), control goes back to step \textcircled{1} above. If the result of the decision is negative, \textcircled{5} the triangle formed by the selected three points is regarded as one segment obtained by division.

These process steps are repeatedly performed for all the feature points. \textcircled{6} A decision is made as to whether all the feature points are included within the triangular mesh. If the result of the decision is negative, control returns to the step \textcircled{1}. If the result of the decision is affirmative, the process sequence is ended.

Referring to FIG. 10

FIG. 10 shows an example of detection of the amount of deviation of a real image pattern of through-holes 61 formed in the lower layer from a design position. The substrate 16 to be exposed is provided with the through-holes 61 and consists of a resin substrate. A photosensitive material has been applied to the substrate. The substrate 16 is photographed to obtain a real image pattern. The center points of the through-holes 61 and alignment patterns 63, 64 are extracted as feature points from the obtained real image pattern by a pattern matching process.

Then, feature points each of which gives a 1:1 correspondence between a corresponding one of the feature points of the real image pattern and a corresponding point given by the design pattern data are judged. The amounts of deviations of the latter feature points from the former feature points are detected.

In this case, positional deviations occur at only three feature points by accident. Obviously, similar processing can be performed even when more feature points produce positional deviations.

To simplify the illustration, it is here assumed that distortion is at balance across the whole substrate and thus the effective exposure area is distortionless as a whole, though the position of each through-hole 61 has deviated from the position of the center point 67 of the through-hole pattern indicated by the design pattern data due to the distortion. Accordingly, the eight alignment patterns 63, 64 formed in the effective exposure area are located at the outer periphery of a rectangle.

Where the whole effective exposure area is distorted and the eight alignment patterns 63, 64 formed at the outer periphery of the effective exposure area are located off the outer periphery of the rectangle, the triangular cells formed by the alignment patterns 63, 64 and the feature points are compared against triangular cells obtained by dividing the design pattern while maintaining the rectangle, and the amounts of the deviations are found in the same way as in the above-described process.

Referring to FIG. 11

FIG. 11 illustrates an example of a method of dividing an area of a real image pattern and modifying the shape of an area of a design pattern. Using feature points on the real image pattern which are detected by the aforementioned processing for extracting feature points, the area of the real image pattern is divided into triangular cells similar to the triangular cells obtained by the design pattern.

In this embodiment, too, triangles to be noticed are hatched.

Operations for performing a conversion to modify the shape of the image such that triangles obtained by dividing the design pattern indicated by the design pattern data agree with their respective triangles obtained by dividing a real image pattern are next described by referring to FIGS. 12-16.

Referring to FIG. 12

FIG. 12 is a diagram illustrating operations for rotating a design pattern area. One of the vertices of the triangle is taken as an origin. The triangle is rotated about the origin such that the base of the triangle enters the first quadrant. The triangle having undergone the rotational operation is expressed by an XY coordinate system.

Let θ be a rotational angle. A coordinate-converting formula used when a rotational operation is performed is given by a matrix represented by Equation (1) shown in the figure.

Referring to FIG. 13

FIG. 13 is a diagram illustrating an operation for converting coordinate axes of a design pattern area. The coordinate axes of a triangle having undergone a rotational operation are converted to form coordinate axes ζ and φ forming two sides of the triangle. A coordinate-converting formula used when this coordinate-converting operation is performed is given by a matrix that is represented by Equation (2) in the figure.

Referring to FIG. 14

FIG. 14 is a diagram illustrating an operation for expanding or contracting conversion from a design pattern area to a real image pattern area. A triangle of a design pattern which has been converted into a triangle defined by the coordinate axes ζ and φ is expanded or contracted by an operation similar to the foregoing operation such that the lengths of the sides become equal to the lengths of the sides of the triangle on the real image pattern defined by coordinate axes ζ′ and φ′.

A coordinate-converting formula used when this coordinate-converting operation is performed is given by a matrix represented by Equation (3) shown in the figure.

Referring to FIG. 15

FIG. 15 is a diagram illustrating an operation for converting coordinates of a pattern area after expansion or contraction. A triangle having undergone an expansion or contraction is converted into an X′Y′ coordinate system by performing an inverse coordinate conversion. A coordinate-converting formula used when this coordinate-converting operation is performed is given by a matrix represented by Equation (4) in the figure.

Referring to FIG. 16

FIG. 16 is a diagram illustrating an operation for rotating a pattern area after expansion or contraction. A triangle converted into the X′Y′ coordinate system is returned to the same direction of rotation as the triangle of the original real image pattern by performing a rotational operation.

A coordinate-converting formula used to perform this coordinate-converting operation is given by a matrix represented by Equation (5) shown in the figure.

The shape of the image can be modified into a triangle on the real image pattern by performing a sequence of operations illustrated in FIGS. 12-16 on the triangular area on the design pattern as described above.

A formula expressing the whole processing for image shape modification is given by a matrix expressed by Equation (6) in FIG. 16.

In the aforementioned processing for modifying the image shape, one triangle of interest is taken as an example, and an algorithm of an operation for shape modification is described. This processing is performed not only on one triangle. Rather, similar processing for shape modification is performed on all the triangles forming a triangular mesh.

Referring to FIG. 17

FIG. 17 is a diagram illustrating an example of creation of a transferred pattern of metal interconnects. An image indicated by design pattern data is modified by the aforementioned image modification processing, thus producing a transferred pattern 68 of metal interconnects as shown. This pattern 68 corresponds to local distortion in the effective exposure area.

Referring to FIG. 18

FIG. 18 shows an example of real image pattern after transfer of the upper layer of metal interconnects. A pattern transfer is performed with the exposure machine 10, using image data obtained from results of the image shape modification of all the triangles. Consequently, the upper layer of metal interconnects 69 can be transferred in a corresponding manner to positional deviations of the through-holes 61 caused by nonuniform distortion on the resin substrate.

Preferably, a hard resin material containing a main component selected from the group consisting of paper-based phenol, glass composite, glass epoxy, diarylphthalate, epoxy resin, oxybenzoyl polyester, polyethylene terephthalate, polyimide, polymethyl methacrylate, polyoxymethylate, polyphenylene ether, polysulfone, and polytetrafluoroethylene is used as the material of the resin substrate. A pattern transfer to the substrate material that easily produces distortion in this way can be performed without breaks or electrical shorts of the interconnects or contacts.

A pattern transfer method according to a second embodiment of the present invention is next described by referring to FIGS. 19-25. The used pattern transfer system, exposure machine, pattern transfer process, method of forming a triangular mesh, and method of modifying shapes of images are identical to their respective counterparts of the first embodiment described above.

Referring to FIG. 19

FIG. 19 is a diagram of pretreatment steps included in a pattern transfer process according to the second embodiment of the invention. \textcircled{1} First, a silicon wafer is cleaned. \textcircled{2} Then, a pattern of regions in which devices will be fabricated are formed by selective oxidation. The regions are surrounded by an oxidation film providing device isolation. \textcircled{3} Then, the silicon wafer having the pattern of regions in which devices will be fabricated is cleaned. \textcircled{4} Then, a gate insulator film is formed by thermal oxidation on the surfaces of the regions in which devices will be fabricated. \textcircled{5} Then, a conductive film made of polycrystalline silicon and used to form gate electrodes is deposited. \textcircled{6} Then, the surface is cleaned. \textcircled{7} Then, a photosensitive material is applied to the top surface of the silicon wafer.

Also, in this case, steps due to the underlying oxide film providing device isolation can be observed through the photosensitive material. The oxide film is formed on the surface of the conductive film for forming the gate electrodes. The steps permit the pattern of regions in which devices will be fabricated to be recognized.

Referring to FIG. 20

FIG. 20 is a diagram showing a design pattern according to the second embodiment of the invention. In this embodiment, transfer of the pattern of MOSFETs fabricated on a silicon wafer is taken as an example. A pattern 71 of regions in which devices will be fabricated is formed in a lower layer. A pattern 72 of gate electrodes is formed in a corresponding manner to the pattern 71.

In this case, too, alignment patterns 73, 74 formed at the four corners of the effective exposure area and in the midpoints of the four sides are also shown.

Referring to FIG. 21

FIG. 21 shows an example of division of an area of a design pattern according to the second embodiment of the invention. The vertices 75 of the rectangle of a pattern 71 of regions in which devices will be fabricated are used as feature points, in addition to alignment patterns 73 and 74 at ends of the effective exposure area. Using these feature points, the area of the design pattern is divided by a triangular mesh in the same way as in the above-described first embodiment.

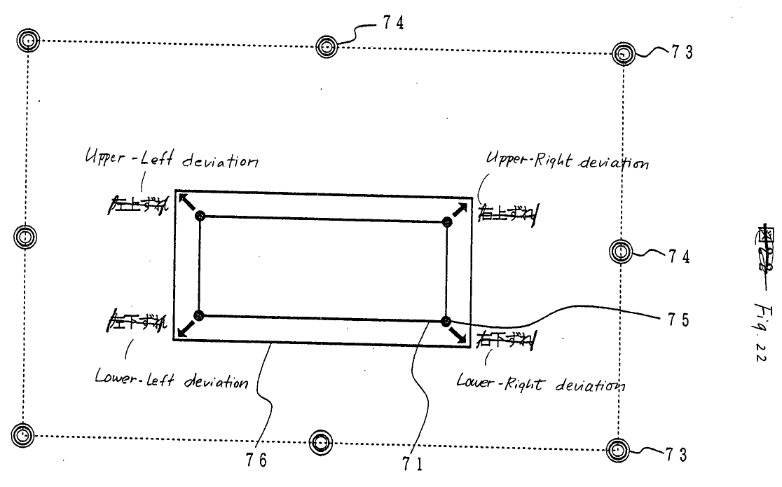

Referring to FIG. 22

FIG. 22 shows an example of detection of the amount of deviation of a real image pattern 76 in a lower layer from a design position. The detection of the amount of deviation is performed by an operation similar to the operation performed in the first embodiment.

In this example, the device isolation regions have been slightly enlarged during the process step of forming the pattern 71 of regions in which devices will be fabricated. It is detected that the vertices 75 of the pattern 71 of the regions in which devices will be fabricated have deviated outwardly similarly.

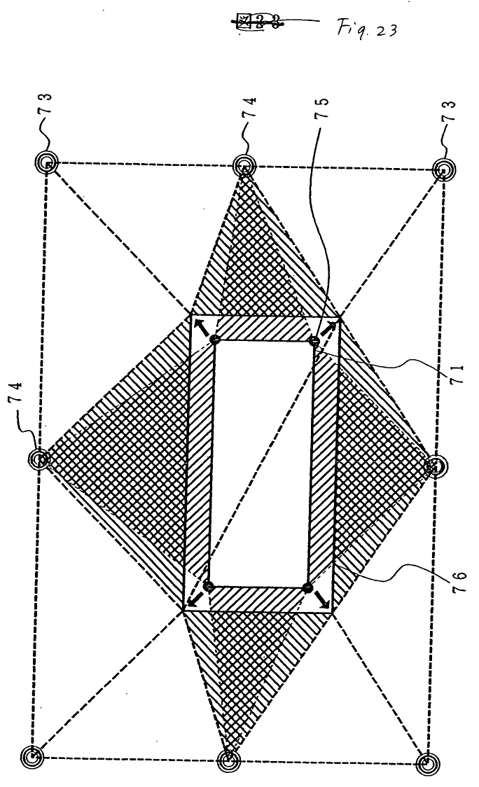

Referring to FIG. 23

FIG. 23 shows an example in which the area of a real image pattern 76 is divided and the shape of a pattern 71 of regions in which devices will be fabricated is modified. The pattern 71 is a design pattern. The area of the real image pattern 76 is divided by a triangular mesh by operations similar to the operations performed in the first embodiment.

Also, in this example, triangles to be noticed are hatched and compared with corresponding ones of the triangles on the design pattern. Obviously, similar operations are subsequently performed on all the triangles on the design pattern.

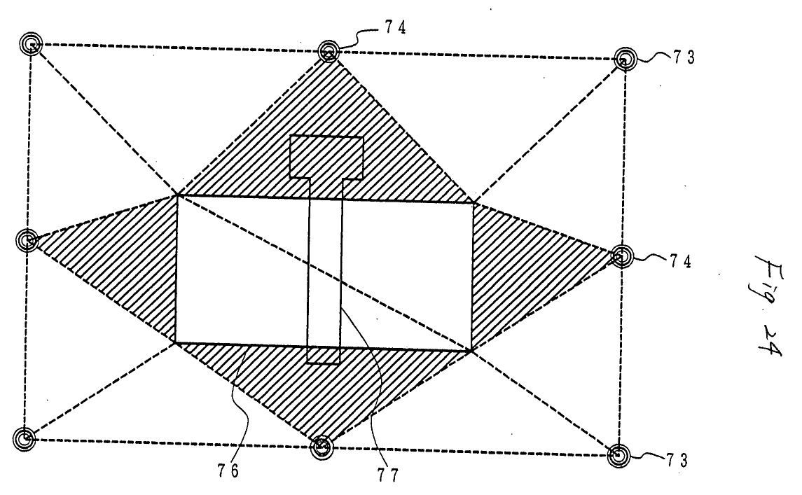

Referring to FIG. 24

FIG. 24 shows an example of generation of a transferred pattern of gates. The shape of the image is modified by operations similar to the operations performed in the first embodiment. This processing for modifying the shape is performed such that all the triangles indicated by the design pattern data match the shapes of the respective triangles on the real image pattern, thus obtaining a transferred pattern 77 of gates.

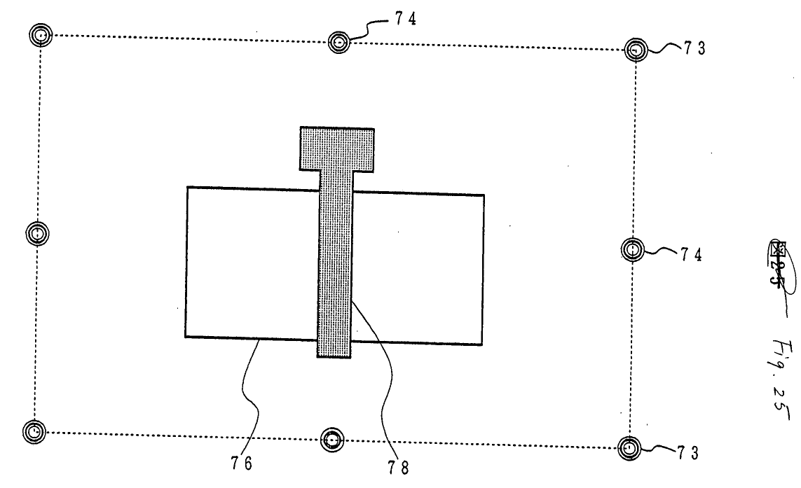

Referring to FIG. 25

FIG. 25 shows an example of a real image pattern after transfer of an upper layer of gate electrodes. A pattern 78 of real image of gate electrodes corresponding to local pattern distortion can be obtained on the silicon wafer by operations exactly identical with the operations performed in the first embodiment.

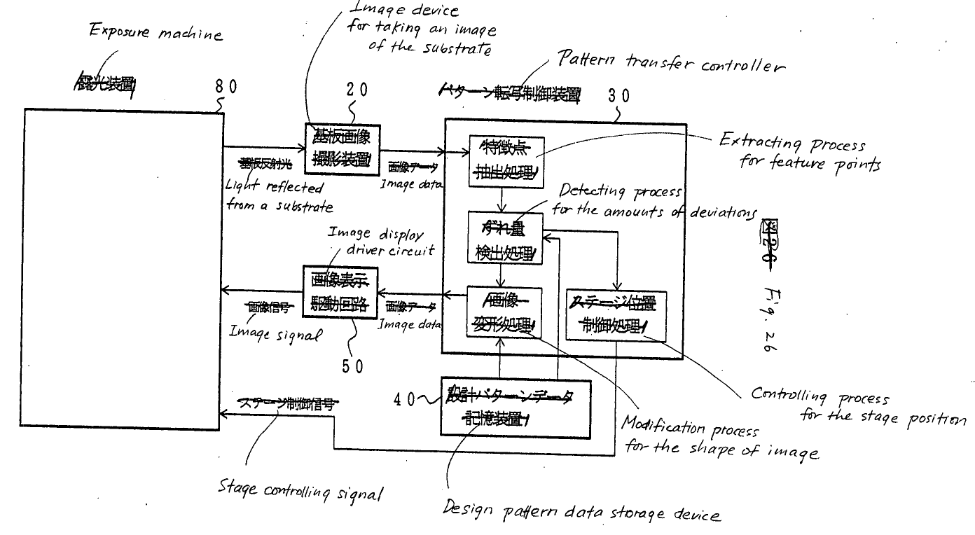

A pattern transfer method according to a third embodiment of the invention is next described by referring to FIGS. 26-29.

Referring to FIG. 26

FIG. 26 is a block diagram of a system for implementing a method of transferring a pattern in accordance with the third embodiment of the invention. This system is similar in configuration with the pattern transfer system of the first embodiment except for the following point. In the third embodiment, an exposure machine 80 is equipped with an accurate positioning stage that is inferior in positioning accuracy to the ultraaccurate positioning stage 15 forming the exposure machine 10 used in the first embodiment. Concomitantly, a function of controlling the stage position is imparted to the pattern transfer controller 30. The position of the accurate positioning stage is controlled according to a stage control signal.

Referring to FIG. 27

FIG. 27 is a conceptual diagram showing one example of the exposure machine 80. This machine is fundamentally similar in configuration with the exposure machine which has been already described in connection with FIG. 3 and corresponds to reduction projection exposure. In this case, however, an accurate positioning stage 85 which is driven by a non-resonant ultrasonic motor and has a repetitive positioning accuracy of more than ±11 nm (when length is taken as a unit) is used as a positioning stage. The position of the accurate positioning stage 85 can be modified according to a stage control signal based on the result of the control over the stage position.

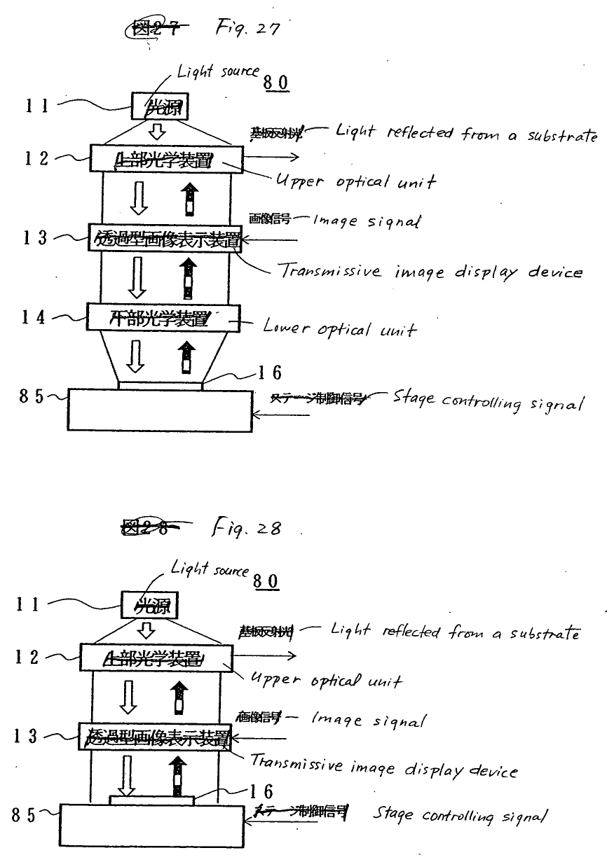

Referring to FIG. 28

FIG. 28 is a conceptual diagram of another example of exposure machine 80. This machine is fundamentally identical in configuration with the exposure machine which has been already described in connection with FIG. 4 and corresponds to proximity exposure. Also, in this case, an accurate positioning stage 85 having a relatively low positioning accuracy is used as a positioning stage that holds the exposed substrate 16. The stage position can be modified according to a stage control signal sent from the pattern transfer controller.

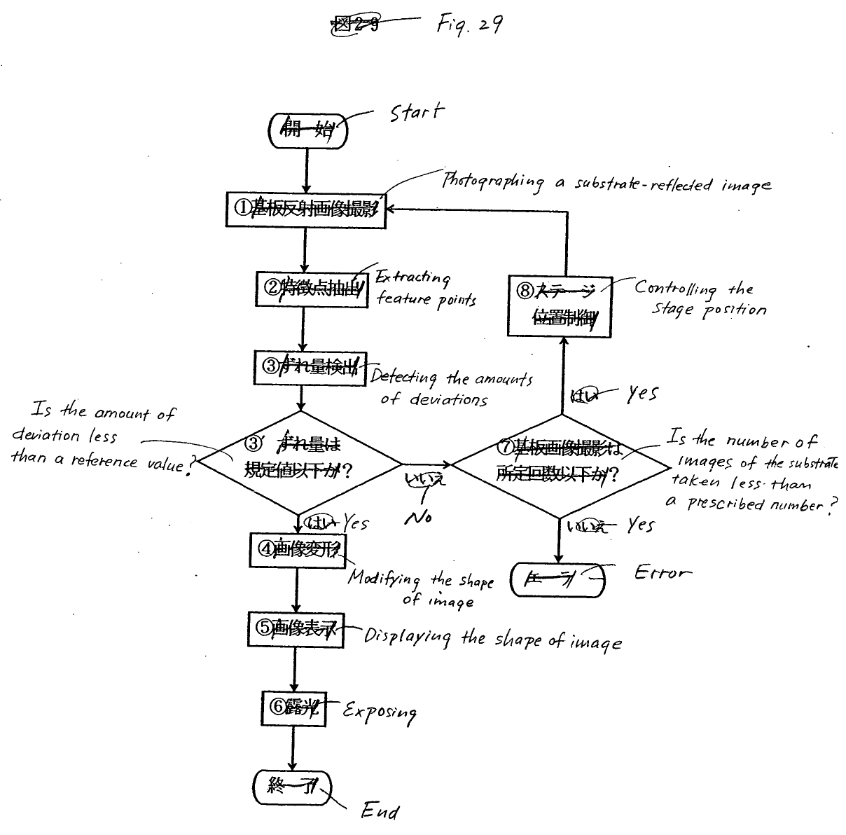

Referring to FIG. 29

FIG. 29 is a diagram illustrating a sequence of operations for transferring a pattern in accordance with the third embodiment of the invention. The sequence of operations is fundamentally identical with the sequence of operations for pattern transfer in the first embodiment described previously in connection with FIG. 5.

In this third embodiment, however, the positioning accuracy of the accurate positioning stage 85 is lower than the required pattern transfer accuracy. Therefore, after the end of detection of the amount of deviation, a decision, or a conditional branch, is made as to whether the amount of deviation is within a prescribed value.

When the outcome of the conditional branch \textcircled{3}′ is that the amount of deviation is less than a reference value, the sequence is similar to the sequence illustrated in FIG. 5. When the amount of deviation exceeds the reference value, \textcircled{7} a decision is made as to whether the number of images of the substrate taken is less than a prescribed number. When the result of the decision is that the number is less than the prescribed number, \textcircled{8} the pattern transfer controller is caused to produce a stage control signal. The position of the accurate positioning stage 85 is varied very slightly according to the stage control signal.

In particular, with respect to a feature point producing the greatest amount of deviation out of the amounts of deviations, the stage is moved an amount equal to the half of the greatest amount of deviation. Then, the sequence is made to proceed again. The amount of deviation is detected and then a conditional branch is executed to determine whether the amount of deviation is within the prescribed value. When the amount of deviation is within the prescribed value, the shape of the image is modified. An exposure pattern is generated, and exposure is performed, thus ending the sequence. When the amount of deviation is greater than the prescribed value, the stage position is again controlled by similar operations.

A conditional branch is included to count the number of taken images of the substrate and to inform the user of the presence of an error when the number exceeds a given number, in order to prevent the cycle from being repeated; otherwise, an infinite loop would be created.

Because of the system configuration and sequential architecture described so far, even where the exposed substrate 16 is held using the accurate positioning stage 85 having a relatively low accuracy, a good pattern transfer can be carried out.

In this way, in the third embodiment of the invention, the cost of the equipment can be reduced by using a general accurate positioning stage. Also, it is possible to cope with wider ranges of exposure systems.

While various embodiments of the present invention have been described so far, the invention is not limited to the structures and conditions described in the embodiments. Rather, various changes and modifications are possible.

For example, in the embodiments described above, a high-resolution area sensor of about 5 million pixels (3008 pixels×1960 pixels) is used to gain real image data from light reflected from a substrate. Where one wants to photograph images at higher resolutions, the whole surface of the effective pattern area can be taken by increasing the magnification factor of the substrate image-taking imaging device at which the reflected light is photographed from the present magnification factor and causing the area sensor to scan the substrate.

When similar operations are used, scanning and reading using line sensors can also be done.

In addition, in the above-described embodiments, 8 alignment patterns are formed in the effective exposure area. The number of the alignment patterns is not limited to 8. Six or 12 alignment patterns may also be employed.

Moreover, in the above-described embodiments, in order to simplify the illustration, the pretreatment for the substrate consists of forming through-holes in the substrate. The pretreatment is not restricted to this process step. Obviously, metal interconnects and through-hole patterns may be previously formed in plural layers.

Additionally, in the above-described embodiments, the effective exposure area is divided by a triangular mesh by making use of feature points. The method of division is not limited to the method of Delaunay triangulation. Moreover, in this case, the triangles are not restricted to triangles close to regular triangles.

Further, in the above-described embodiments, dedicated patterns are formed as the alignment patterns. The patterns are not always limited to dedicated patterns. Patterns having also functions necessary for a printed wiring board may also be used as alignment patterns.

For example, threaded holes formed to mount a printed wiring board to an electronic apparatus may be used as such non-dedicated patterns. Where the exposed substrate is smaller than the effective exposure area, the corners of the substrate may be used as alignment patterns.

In the first embodiment described above, when feature points are extracted, through-holes are used as the feature points. Corners or center points of bends of an interconnect pattern may also be used.

Additionally, each interconnect pattern may be typified by its center line and treated as a straight line or bent line (including a curved line). Both ends, midpoint, or bending points of the straight or bending line may also be used as feature points.

In the second embodiment described above, when feature points are extracted, the vertices of a rectangle that is the shape of the pattern of regions in which devices are fabricated are used as the feature points. The feature points are not limited to vertices. The midpoints of sides, center of gravity, or other points may also be used.

Where the real pattern forming a base layer is a nonrectangular polygon, characteristic points of the polygonal pattern such as vertices, midpoints of sides, or center of gravity may be used as feature points.

Furthermore, in the second embodiment described above, a silicon wafer is used as a substrate to be exposed. The substrate is not limited to a silicon wafer. For example, the invention can also be applied to a process step of transferring an IC pattern on a transparent glass substrate or ceramic substrate. Consequently, TFT substrates or SIPs forming active matrix liquid crystal displays can be fabricated at high throughput.

In addition, in the above-described various embodiments, alignment patterns previously formed on a substrate are used. If necessary, additional alignment patterns may be transferred together with an IC pattern during pattern transfer step.

Moreover, in the above-described embodiments, it is necessary to previously calibrate the positional relation between the positions of pixels on a transmissive image display device and the respective pixels on the substrate image-taking imaging device for photographing light reflected from the substrate, the reflected light being obtained through the transmissive image display device.

In this case, one example of the calibration is done as follows. Only one pixel of the transmissive image display device is made non-transmissive. This pixel is moved across the whole region. At this time, an image is taken by the substrate image-taking imaging device. It is detected from the taken image as to what one of the imaging pixels of the imaging device corresponds one pixel of the transmissive image display device to.

Further, in the description of the above-described embodiments, the pattern to be transferred is a wiring pattern formed on a printed wiring board or an electrode pattern of a semiconductor device. The invention is not limited to transfer of such a pattern. The invention is applied to transfer of various kinds of patterns such as a pattern of an insulating film or other device.

For example, in an electronic paper made of a sheet of PET (polyethylene terephthalate) on which a display device is formed, the PET sheet has flexibility and easily deforms thermally. Therefore, during manufacturing steps, distortion tends to be produced. Use of the pattern transfer method of the invention assures electrical connection between various elements formed in different layers.

In the case of a System-in-Package (SIP), it is necessary that a semiconductor chip on which devices have been completed be stuck on a mounting substrate and that interconnects be connected from connector terminals of the semiconductor chip to connector terminal on the mounting substrate. Also, in this case, so-called “superconnect” using thin interconnects of about 1 to 10 μm can be achieved.

When a solar cell array is directly fabricated on a building material such as a roof, an interconnect pattern may be formed in a mask-free or reticle-free manner by applying the present invention.

In this case, it is considered that a relatively thick pattern is used. Therefore, it is desirable to adopt magnified projection exposure. In this case, the lower optical unit of the exposure machine of the reduction projection exposure system shown in FIG. 3 may be constructed as an enlarging optical system.

Further, in the first embodiment, an ultraaccurate positioning stage is used and so the position of the stage is not controlled according to a stage control signal as in the second embodiment. In a case where higher positioning accuracy is required in future, the stage may be controlled extremely accurately according to a stage control signal.

Additionally, in the above-described embodiments, the exposure machine is described as a narrowly defined exposure machine having no pattern transfer controller. The exposure machine may also be a widely defined exposure machine, or exposure equipment, comprising a narrowly defined exposure machine incorporating a pattern transfer controller as in the whole configuration of the pattern transfer system shown in FIG. 2 or 26.

### INDUSTRIAL APPLICABILITY

As described so far, the present invention makes it possible to perform a pattern transfer assuring formation of interconnects, contacts, or devices without producing electrical troubles to cope with deviation of the shape of a microlithography pattern due to nonuniform distortion on a substrate. This greatly contributes to improvement of throughput in manufacturing of various electronic devices and electronic apparatus and to reduction of manufacturing cost.

1. A pattern transfer method comprising the steps of:
performing processing for extracting feature points from image data obtained by photographing a substrate to be exposed, the substrate having been pretreated in a given manner;
performing processing for detecting amounts of deviations from comparison of results of said extraction of feature points and design pattern data to be exposed;
performing processing for modifying shapes of images in said design pattern data using results of said processing for detecting amounts of deviations;
causing an exposed image generator to produce the images obtained by results of said processing for modifying shapes of images as an exposure pattern; and
exposing said exposure pattern onto said substrate to be exposed.

2. A pattern transfer method as set forth in claim 1, wherein said design pattern data is any one of a printed wiring circuit pattern, a semiconductor circuit pattern, and a circuit pattern made of a combination thereof.

3. A pattern transfer method as set forth in claim 1, wherein in said pretreatment of the exposed substrate, there is the step of previously forming at least one layer of pattern in said design pattern data, and wherein a film of a photosensitive material is subsequently applied to a top surface of said substrate to be exposed.

4. A pattern transfer method as set forth in claim 3, wherein in said pretreatment of the exposed substrate, at least four alignment patterns are formed in end portions of an effective area from which an image can be taken when light reflected from said substrate is photographed by said substrate image-taking imaging device, in addition to said design pattern.

5. A pattern transfer method as set forth in claim 4, wherein in said processing for extracting feature points, through-holes are used as the feature points, in addition to said alignment patterns.

6. A pattern transfer method as set forth in claim 4, wherein in said processing for extracting feature points, characteristic points at least around or inside a polygonal pattern or characteristic points on a straight or curved line are used as feature points, in addition to said alignment patterns.

7. A pattern transfer method as set forth in claim 1, wherein in said processing for detecting amounts of deviations, amounts of relative positional deviations are calculated for all feature points corresponding to both said image data and said design pattern data in a 1:1 relation.

8. A pattern transfer method as set forth in claim 7, wherein said processing for modifying shapes of images is carried out by dividing areas by a triangular mesh having identical meshes for said image data and said design pattern data by the use of all the feature points corresponding in a 1:1 relation as described above as vertices and bringing the shapes of the triangles in the triangular mesh in said design pattern data into agreement with the shapes of the respective triangles in the triangular mesh in said image data.

9. A pattern transfer method as set forth in claim 8, wherein in said processing for modifying shapes of images, an affine transform is used.

10. A pattern transfer method as set forth in claim 1, wherein in a case where the position of said exposed substrate is controlled using an accurate positioning stage having a repetitive positioning accuracy of more than ±11 nm (when length is taken as a unit), processing for controlling the position of the stage is performed from results of said processing for detecting amounts of deviations, a stage control signal in a given format is produced, and said accurate positioning stage is driven for physically moving said exposed substrate to thereby perform control in which the amount of relative positional deviation of at least one feature point corresponding in a 1:1 relation as described above is reduced to a minimum prior to pattern transfer.

11. A pattern transfer method as set forth in claim 1, wherein the material of said exposed substrate is a hard resin material containing a main component that is paper-based phenol, glass composite, glass epoxy, diarylphthalate, epoxy resin, oxybenzoyl polyester, polyethylene terephthalate, polyimide, polymethyl methacrylate, polyoxymethylane, polyphenylene ether, polysulfone, or polytetrafluoroethylene.

12. A pattern transfer method as set forth in claim 11, wherein a single-crystal silicon region is present at least in a part of the exposed substrate made of said hard resin material.

13. A pattern transfer method as set forth in claim 1, wherein said exposed substrate is made of any one of silicon wafer, transparent glass material, and ceramics.

14. An exposure machine having means for holding a substrate to be exposed and for producing an arbitrary exposure pattern according to input of an image signal, the substrate having been pretreated in a given manner, said exposure machine having a pattern transfer system comprising:
optics for guiding light reflected from the exposed substrate into a substrate image-taking imaging device;
said substrate image-taking imaging device photographing the light reflected from the substrate via said optics and gaining the photographed light as image data;
an image signal creating device for creating said image signal;
a pattern transfer controller for receiving the image data output from said substrate image-taking imaging device and outputting the image data to said image signal creating device; and
a design pattern data storage device having a function of transferring design pattern data to said pattern transfer controller;
wherein said pattern transfer controller has a function of performing processing for extracting feature points from the image data obtained from said substrate image-taking imaging device, performing processing for detecting amounts of deviations from results of said extraction of feature points and from said design pattern data, performing processing for modifying the shapes of images in said design pattern data using results of said processing for detecting amounts of deviations, and using the images obtained by results of said processing for modifying shapes of images as image data for said image signal creating device.

15. An exposure machine as set forth in claim 14, wherein said means for producing an arbitrary exposure pattern according to input of the image signal has a transmissive image display device.

16. An exposure machine as set forth in claim 15, wherein said substrate image-taking imaging device is placed in a position where light reflected from the substrate is photographed after passage through said transmissive image display device.

17. An exposure machine as set forth in any one of claims 15 and 16, wherein said transmissive image display device is a transmissive liquid crystal display.

18. An exposure machine as set forth in claim 14, wherein said exposure machine adopts a reduction projection exposure system.

19. An exposure machine as set forth in claim 14, wherein said exposure machine adopts a proximity exposure system.

20. An exposure machine as set forth in claim 14, wherein said exposure machine adopts a magnified projection exposure system.

21. An exposure machine as set forth in claim 14, wherein there is provided an ultraaccurate positioning stage having a repetitive positioning accuracy of less than ±11 nm (when length is taken as a unit) for a mechanism for controlling the position of said exposed substrate.

22. An exposure machine as set forth in claim 14, wherein there is provided an accurate positioning stage having a repetitive positioning accuracy of more than ±11 nm (when length is taken as a unit) for a mechanism for controlling the position of said exposed substrate, the stage controlling the position of the exposed substrate according to a stage control signal transmitted from said pattern transfer controller.

23. An exposure machine as set forth in any one of claims 21 and 22, wherein said positioning stage has a non-resonant ultrasonic motor as a driving mechanism.
